(19) United States
(12) Patent Application Publication
(10) Pub. No.: US 2026/0319162 A1
(43) Pub. Date: Oct. 15, 2026

(54) ELECTRONIC DEVICE

(71) Applicant: InnoLux Corporation, Miao-Li County (TW)

(72) Inventors: Fu-Wei CHAO, Miao-Li County (TW); Shu-I LIN, Miao-Li County (TW)

(73) Assignee: InnoLux Corporation, Miao-Li County (TW)

(21) Appl. No.: 19/466,487

(22) Filed: Feb. 1, 2026

(30) Foreign Application Priority Data
Feb. 13, 2025 (CN) 202510158469.6

(51) Int. Cl. F21V 8/00

(52) U.S. Cl. CPC G02B 6/009; G02B 6/0031; G02B 6/0066

(57) ABSTRACT

An electronic device includes a back frame, a light emitting circuit and a light guide plate. The back frame has a turning structure including a bottom part, a top part and a side part connected between the bottom part and the top part. The light guide plate and the light emitting circuit are fixed through a first fixing component and disposed in the turning structure. The light emitting circuit includes a first protecting layer, a first adhesive layer, a first conductive layer, a base film, a second conductive layer, a second adhesive layer and a second protecting layer which are stacked sequentially from top to bottom. The base film has an end part protruding from the first protecting layer, the first adhesive layer, the second adhesive layer and the second protecting layer, and the end part is adjacent to the side part of the turning structure.

### BACKGROUND OF THE DISCLOSURE

### 1. Field of the Disclosure

The present disclosure relates to an electronic device, and more particularly to an electronic device with high yield rate and high quality.

### 2. Description of the Prior Art

During a manufacturing process or an assembly process of an electronic device (e.g., a display device, a lighting device, etc.), defects (e.g., damages, dents, additional material residues, etc.) affecting the yield rate and/or quality of the electronic device may occur. In order to reduce the defects generated in the manufacturing process or assembly process, some structures in the electronic device need to be designed accordingly.

### SUMMARY OF THE DISCLOSURE

According to an embodiment, the present disclosure provides an electronic device including a back frame, a light emitting circuit and a light guide plate. The back frame has a turning structure, wherein the turning structure includes a bottom part, a top part and a side part connected between the bottom part and the top part. The light guide plate and the light emitting circuit are fixed through a first fixing component. The light emitting circuit and the light guide plate fixed to each other are disposed in the turning structure. The light emitting circuit includes a first protecting layer, a first adhesive layer, a first conductive layer, a base film, a second conductive layer, a second adhesive layer and a second protecting layer which are stacked sequentially from top to bottom. The base film has an end part protruding from the first protecting layer, the first adhesive layer, the second adhesive layer and the second protecting layer, and the end part is adjacent to the side part of the turning structure.

### BRIEF DESCRIPTION OF THE DRAWINGS

FIG. 1 is a schematic diagram showing a cross-sectional view of an electronic device according to a first embodiment of the present disclosure.

FIG. 2 is a schematic diagram showing a cross-sectional view of a light emitting circuit according to an embodiment of the present disclosure.

FIG. 3 is a schematic diagram showing a top view of a light emitting circuit according to an embodiment of the present disclosure.

FIG. 4 is a schematic diagram showing a part of an assembly process of an electronic device according to an embodiment of the present disclosure.

FIG. 5 is a schematic diagram showing a top view of a light emitting circuit according to another embodiment of the present disclosure.

FIG. 6 is a schematic diagram showing a cross-sectional view of an electronic device according to a second embodiment of the present disclosure.

FIG. 7 is a schematic diagram showing a cross-sectional view of an electronic device according to a third embodiment of the present disclosure.

FIG. 8 is a schematic diagram showing a cross-sectional view of an electronic device according to a fourth embodiment of the present disclosure.

### DETAILED DESCRIPTION

The present disclosure may be understood by reference to the following detailed description, taken in conjunction with the drawings as described below. It is noted that, for purposes of illustrative clarity and being easily understood by the readers, various drawings of this disclosure show a portion of an electronic device in this disclosure, and certain elements in various drawings may not be drawn to scale. In addition, the number and dimension of each device shown in drawings are only illustrative and are not intended to limit the scope of the present disclosure.

Certain terms are used throughout the description and following claims to refer to particular components. As one skilled in the art will understand, electronic equipment manufacturers may refer to a component by different names. This document does not intend to distinguish between components with the same function but different names.

It will be understood that when a component or layer is referred to as being “connected to” another component or layer, it can be directly connected to this another component or layer, or intervening components or layers may be presented. In contrast, when a component is referred to as being “directly connected to” another component or layer, there are no intervening components or layers presented. In addition, when the component is referred to “be coupled to/with another component (or the variant thereof)”, it may be directly connected to this another component, or may be indirectly connected (such as electrically connected) to this another component through other component(s).

In the description and following claims, the term “horizontal direction” generally means a direction parallel to a horizontal plane, the term “horizontal plane” generally means a surface parallel to a direction X and direction Y in the drawings, the term “vertical direction” and the term “top-view direction” generally means a direction parallel to a direction Z and perpendicular to the horizontal direction in the drawings, and the direction X, the direction Y and the direction Z are perpendicular to each other. In the description and following claims, the term “top view” generally means a viewing result viewing along the vertical direction. In the description and following claims, the term “cross-sectional view” generally means a structure cut along the vertical direction is viewed along the horizontal direction.

It should be noted that the technical features in different embodiments described in the following can be replaced, recombined, or mixed with one another to constitute another embodiment without departing from the spirit of the present disclosure.

In the present disclosure, the electronic device may include a display device, a lighting device, a tiled device or a combination thereof, but not limited thereto. The light emitting device may be capable of generating light, so as to serve as a light source (e.g., a backlight module), a display device capable of displaying or other suitable light emitting device.

For example, in the following, the electronic device may be a lighting device capable of emitting light or a display device capable of displaying.

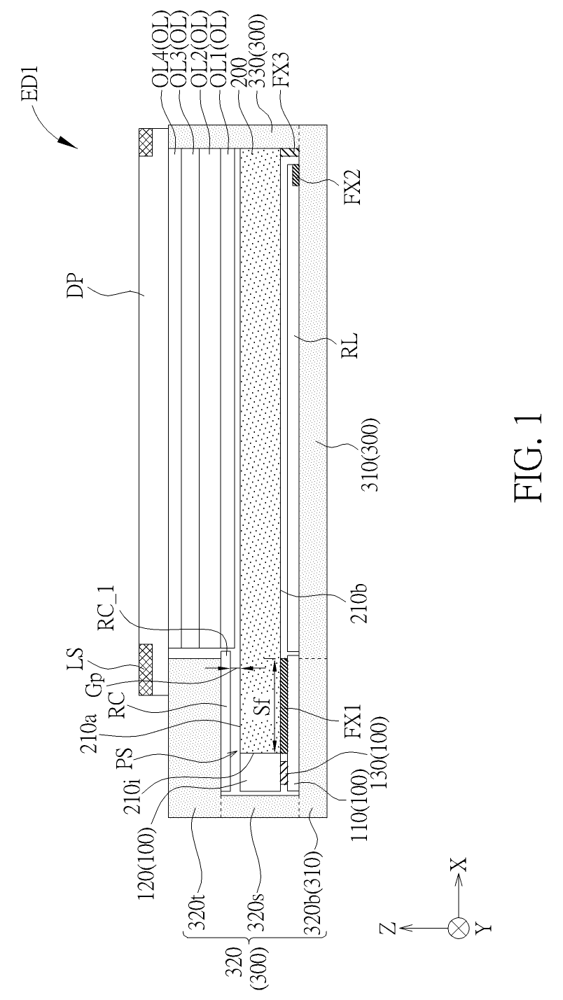

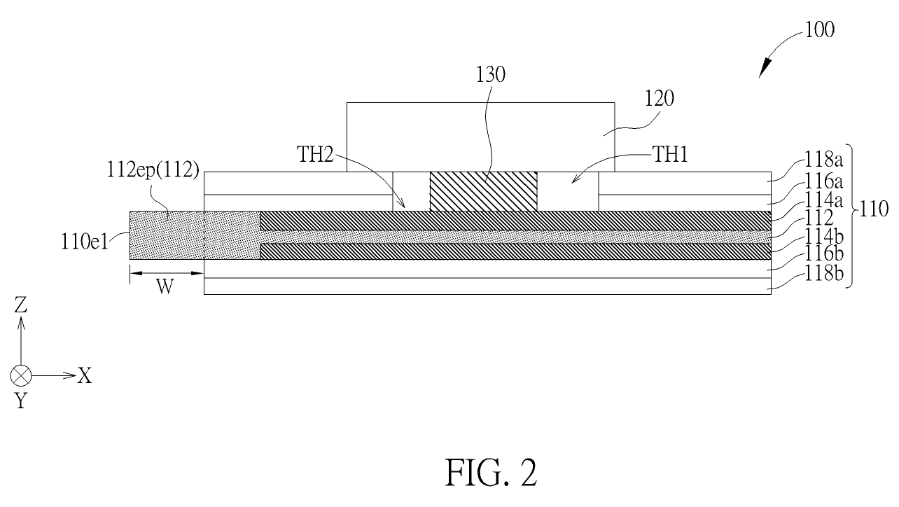

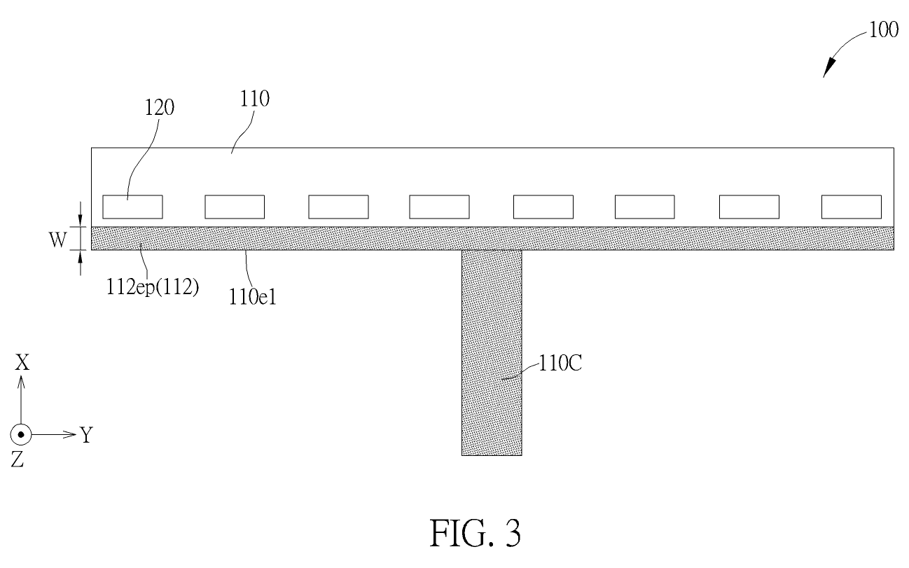

Referring to FIG. 1 to FIG. 3, FIG. 1 is a schematic diagram showing a cross-sectional view of an electronic device according to a first embodiment of the present disclosure, FIG. 2 is a schematic diagram showing a cross-sectional view of a light emitting circuit according to an embodiment of the present disclosure, and FIG. 3 is a schematic diagram showing a top view of a light emitting circuit according to an embodiment of the present disclosure. As shown in FIG. 1 to FIG. 3, the electronic device ED1 includes a light emitting circuit 100, the light emitting circuit 100 includes a board 110 configured to carry structures and/or components disposed thereon, wherein the conductive structure(s) in the board 110 may be electrically connected to the electronic component(s) disposed on the board 110. In some embodiments, the board 110 includes a circuit board containing conductive material(s). The board 110 includes a circuit board with a laminate (e.g., a copper clad laminate (CCL)) or any other suitable circuit board, but not limited thereto.

In the present disclosure, the board 110 may include at least one conductive layer ant at least one insulating layer, and the board 110 may optionally include any other suitable layer, wherein the material of the conductive layer may include metal, other suitable conductive material(s) or a combination thereof, and the material of the insulating layer may include organic insulating material(s), inorganic insulating material(s) or a combination thereof. In FIG. 2, the board 110 may include a first protecting layer 118a (an insulating layer), a first adhesive layer 116a (an insulating layer), a first conductive layer 114a, a base film 112 (an insulating layer), a second conductive layer 114b, a second adhesive layer 116b (an insulating layer) and a second protecting layer 118b (an insulating layer) stacked in sequence, but not limited thereto.

The base film 112 may be rigid or flexible to correspondingly make the board 110 be rigid or flexible, and the base film 112 may include suitable material based on its type. The base film 112 may include glass, quartz, ceramic, sapphire, silicon, polymer (e.g., polyimide (PI), polyethylene terephthalate (PET), etc.), any other suitable material or a combination thereof.

In FIG. 2, the base film 112 may be between the first conductive layer 114a and the second conductive layer 114b, wherein a portion of the first conductive layer 114a and a portion of the second conductive layer 114b may be electrically connected to each other through a via (not shown in figures), and a portion of the first conductive layer 114a and a portion of the second conductive layer 114b may be electrically connected to the electronic component(s) disposed on the board 110, so as to form a suitable circuit. The material of the first conductive layer 114a and the material of the second conductive layer 114b may include any suitable metal (e.g., copper), but not limited thereto.

The base film 112, the first conductive layer 114a and the second conductive layer 114b may be between the first protecting layer 118a and the second protecting layer 118b, such that the first protecting layer 118a and the second protecting layer 118b may be disposed on two opposite sides of the base film 112, the first conductive layer 114a and the second conductive layer 114b, so as to protect the base film 112, the first conductive layer 114a and the second conductive layer 114b. In the present disclosure, the first protecting layer 118a and the second protecting layer 118b may include any suitable insulating material (e.g., organic insulating material(s), inorganic insulating material(s) or a combination thereof). The first protecting layer 118a may be adhered to the first conductive layer 114a through the first adhesive layer 116a (i.e., the first adhesive layer 116a may be between the first protecting layer 118a and the first conductive layer 114a), and the second protecting layer 118b may be adhered to the second conductive layer 114bthrough the second adhesive layer 116b (i.e., the second adhesive layer 116b may be between the second protecting layer 118b and the second conductive layer 114b). In the present disclosure, the first adhesive layer 116a and the second adhesive layer 116b may include any suitable adhesive material(s). For example, the first adhesive layer 116a and the second adhesive layer 116b may include epoxy resin, but not limited thereto.

In the manufacturing process of the board 110, the first conductive layer 114a and the second conductive layer 114b may be respectively formed on opposite sides of the base film 112. Then, the first protecting layer 118a and the first adhesive layer 116a may be adhered to the first conductive layer 114a by any suitable method, and the second protecting layer 118b and the second adhesive layer 116b may be adhered to the second conductive layer 114b by any suitable method. For example, by a single vacuum hot pressing process, the first protecting layer 118a and the first adhesive layer 116a may be adhered to the first conductive layer 114a, and the second protecting layer 118b and the second adhesive layer 116b may be adhered to the second conductive layer 114b, but not limited thereto.

In FIG. 1 and FIG. 2, the light emitting circuit 100 includes a light emitting unit 120 disposed on the board 110, wherein the light emitting unit 120 is configured to generate light. The light emitting unit 120 may be any component capable of generating light. The light emitting unit 120 may include a LED (e.g., an OLED, a mini LED, a micro LED or a quantum dot LED), but not limited thereto. In the present disclosure, the color of the light generated by the light emitting unit 120 may be designed based on requirement(s). For instance, the light generated by the light emitting unit 120 may be white light, blue light or light with other suitable color.

In FIG. 1 and FIG. 2, the light emitting unit 120 may be electrically connected to the conductive structure in the board 110 through a connecting element 130. The light emitting unit 120 may be electrically connected to a pad within the first conductive layer 114a through the connecting element 130, so as to be electrically connected to a conductive path including the first conductive layer 114a and/or the second conductive layer 114b in the board 110. In FIG. 2, the first protecting layer 118a may have a first hole TH1, the first adhesive layer 116a may have a second hole TH2, the pad within the first conductive layer 114a may be corresponding to the first hole TH1 and the second hole TH2, and the connecting element 130 may be disposed in the first hole TH1 and the second hole TH2 and disposed on the pad, such that the light emitting unit 120 may be electrically connected to the pad within the first conductive layer 114a through the connecting element 130 in the first hole TH1 and the second hole TH2. In the present disclosure, the connecting element 130 may include suitable conductive material. For instance, the connecting element 130 may include a solder or a solder pad, but not limited thereto. In the direction Z, the first hole TH1 may overlap the second hole TH2, and a contour of the first hole TH1 and a contour of the second hole TH2 may be the same or different. In the direction X or the direction Y, a width of the first hole TH1 and a width of the second hole TH2 may be the same or different.

In FIG. 1, the electronic device ED1 includes a light guide plate 200 disposed on a portion of the light emitting circuit 100 and adjacent to the light emitting unit 120, wherein the light guide plate 200 is configured to adjust an incident light, so as to control a direction of light emitted from the light guide plate 200 (e.g., the light entering the light guide plate 200 may be reflected and/or refracted because of the design of the light guide plate 200), thereby achieving appropriate light guide effect. In the present disclosure, the light guide plate 200 may include suitable material(s) with high light transmittance based on requirement(s). For instance, the light guide plate 200 may include PI, polycarbonate (PC), any other suitable material or a combination thereof.

In FIG. 1, the light guide plate 200 may include a light incident surface 210i, the light may enter the light guide plate 200 from the light incident surface 210i of the light guide plate 200, wherein the light incident surface 210i (a side surface of the light guide plate 200) may be designed based on requirement(s). Moreover, the light guide plate 200 may include a first surface 210aand a second surface 210b opposite to each other, the first surface 210a and the second surface 210b may not be parallel to the light incident surface 210i, and the light incident surface 210i may be connected between the first surface 210a and the second surface 210b. In some embodiments, the light entering the light guide plate 200 from the light incident surface 210i may exit the light guide plate 200 from the first surface 210a and/or the second surface 210b. For example, in FIG. 1, the first surface 210a of the light guide plate 200 may face a user during the operation of the electronic device ED1.

In FIG. 1, the light emitting circuit 100 includes the light emitting unit 120 disposed adjacent to the light incident surface 210i of the light guide plate 200, such that the light generated by the light emitting unit 120 may enter the light guide plate 200 from the light incident surface 210i. For example, the light emitting unit 120 may be in contact with the light guide plate 200, such that the light generated by the light emitting unit 120 may effectively enter the light guide plate 200 to increase the intensity of the light, and a deviation between the light emitting unit 120 and the light guide plate 200 which is caused by a difference between their thermal expansion coefficients in the condition of changing temperature may be reduced (e.g., since the light emitting unit 120 may be in contact with the light guide plate 200, a gap caused by changing temperature does not exist between the light emitting unit 120 and the light guide plate 200, so as to reduce a gap deviation caused by changing temperature), thereby enhancing the light-emitting quality of the electronic device ED1.

In the present disclosure, the light guide plate 200 and the board 110 of the light emitting circuit 100 may be fixed through a fixing component FX1. As shown in FIG. 1, the fixing component FX1 may be disposed between the light guide plate 200 and the board 110 of the light emitting circuit 100, and the fixing component FX1 may include suitable material and fix the light guide plate 200 and the board 110 of the light emitting circuit 100 through suitable method. The fixing component FX1 may have adhesion, such that the light guide plate 200 and the light emitting circuit 100 may be adhered to each other through the fixing component FX1, but not limited thereto. The fixing component FX1 may include a tape (e.g., a double-sided tape), an adhesive strip or any other suitable adhesive structure.

Sizes of the fixing component FX1 may be designed based on requirement(s). For instance, in FIG. 1, the size Sf of the fixing component FX1 in the direction X may be less than or equal to 4 mm, less than or equal to 3 mm, less than or equal to 2 mm, or less than or equal to 1 mm, but not limited thereto. Both the size Sf (e.g., a width) of the fixing component FX1 in the direction X and another size (e.g., a width) of the fixing component FX1 in the direction Y may be 1 mm approximately, but not limited thereto.

After the light guide plate 200 and the light emitting circuit 100 are fixed through the fixing component FX1, the light guide plate 200, the light emitting circuit 100 and the fixing component FX1 may be combined into a preassembling structure PS.

As shown in FIG. 1, the electronic device ED1 includes a back frame 300 configured to protect the structures in the electronic device ED1, wherein the back frame 300 may include any suitable material based on requirement(s). For instance, the back frame 300 may include metal (e.g., iron) or other suitable rigid material, so as to have a function of protecting the electronic device ED1, but not limited thereto.

As shown in FIG. 1, the back frame 300 may have a bottom structure 310 configured to carry structures disposed on the back frame 300. In FIG. 1, the bottom structure 310 may be disposed for being substantially parallel to the horizontal plane (i.e., the bottom structure 310 may be substantially parallel to the direction X and the direction Y), but not limited thereto.

As shown in FIG. 1, the back frame 300 may have a turning structure 320, wherein the turning structure 320 may include a bottom part 320b, a top part 320t and a side part 320s connected between the bottom part 320b and the top part 320t, such that the turning structure 320 may be a U-shaped structure in the cross-sectional view. The bottom part 320band the top part 320t may be overlapped with each other in the direction Z and substantially parallel to each other, the side part 320s may be substantially perpendicular to the bottom part 320b and the top part 320t, and the bottom part 320b may be a portion of the bottom structure 310, but not limited thereto.

As shown in FIG. 1, the back frame 300 may optionally include an opposite-side structure 330 opposite to the turning structure 320, wherein the bottom structure 310 may be connected between the opposite-side structure 330 and the turning structure 320. For instance, the opposite-side structure 330 may be substantially perpendicular to the bottom structure 310, but not limited thereto.

As shown in FIG. 1, the preassembling structure PS including the light guide plate 200, the light emitting circuit 100 and the fixing component FX1 may be disposed (assembled) on the bottom structure 310 of the back frame 300 and be disposed (assembled) in the turning structure 320 of the back frame 300, wherein at least a portion of the light emitting circuit 100 and at least a portion of the light guide plate 200 may be disposed in the turning structure 320. As shown in FIG. 1, the light emitting unit 120 of the light emitting circuit 100 may be completely disposed in the turning structure 320, a portion of the light guide plate 200 and a portion of the board 110 of the light emitting circuit 100 may be disposed in the turning structure 320, and a side of the light guide plate 200 opposite to the light emitting unit 120 may be adjacent to or in contact with the opposite-side structure 330 of the back frame 300, but not limited thereto. For instance (not shown in figures), the light emitting circuit 100 may be disposed in the turning structure 320, a portion of the light guide plate 200 may be disposed in the turning structure 320, and a side of the light guide plate 200 opposite to the light emitting unit 120 may be adjacent to or in contact with the opposite-side structure 330 of the back frame 300, but not limited thereto.

In order to make the preassembling structure PS be disposed on the bottom structure 310 and disposed in the turning structure 320 well, the light guide plate 200 and a side of the back frame 300 away from (or opposite to) the turning structure 320 may be fixed through a fixing component FX3. The fixing component FX3 may be disposed on a side of the light guide plate 200 opposite to the light emitting unit 120, so as to fix the light guide plate 200 and a side of the back frame 300 away from (or opposite to) the turning structure 320. The fixing component FX3 may be disposed on the bottom structure 310 and/or the opposite-side structure 330 of the back frame 300, such that a side of the light guide plate 200 opposite to the light emitting unit 120 may be fixed to the bottom structure 310 and/or the opposite-side structure 330 of the back frame 300 through the fixing component FX3, but not limited thereto. The fixing component FX3 may include any suitable adhesive material to have adhesion, such that the light guide plate 200 and the back frame 300 may be adhered to each other through the fixing component FX3, but not limited thereto.

As shown in FIG. 1, the electronic device ED1 may further include a reflective plate RL, wherein the reflective plate RL may be disposed on the bottom structure 310 of the back frame 300 and disposed under the light guide plate 200 (i.e., the reflective plate RL may be disposed between the bottom structure 310 of the back frame 300 and the second surface 210b of the light guide plate 200). By the reflective plate RL, the light emitted from the second surface 210b of the light guide plate 200 may be reflected back to the light guide plate 200 by the reflective plate RL, thereby enhancing the intensity of the light of the electronic device ED1 and the light-emitting quality of the electronic device ED1. In the present disclosure, the reflective plate RL may include material(s) with high light reflectivity. The material of the reflective plate RL may include metal material(s) with high light reflectivity. For example, the reflective plate RL may include silver, aluminum, molybdenum, any other suitable metal material, and other suitable material with high light reflectivity or a combination thereof, but not limited thereto.

In some embodiments, the reflective plate RL may overlap or not overlap the top part 320t of the turning structure 320 of the back frame 300 in the direction Z (in FIG. 1, the reflective plate RL may not overlap the top part 320t of the turning structure 320 of the back frame 300 in the direction Z).

In some embodiments (as shown in FIG. 1), the reflective plate RL may be fixed between the bottom structure 310 of the back frame 300 and the light guide plate 200 through a fixing component FX2. For example (as shown in FIG. 1), the fixing component FX2 may be disposed on a side of the reflective plate RL opposite to the light emitting unit 120, so as to fix the reflective plate RL and a side of the back frame 300 away from (or opposite to) the turning structure 320 (i.e., the reflective plate RL and a side of the back frame 300 away from the turning structure 320 are fixed through the fixing component FX2), but not limited thereto. In some embodiments, the fixing component FX2 may be disposed on the bottom structure 310 and/or the opposite-side structure 330 of the back frame 300, such that a side of the reflective plate RL opposite to the light emitting unit 120 may be fixed to the bottom structure 310 and/or the opposite-side structure 330 of the back frame 300 through the fixing component FX2. For example, the fixing component FX2 may include any suitable adhesive material to have adhesion, such that the reflective plate RL and the back frame 300 may be adhered to each other through the fixing component FX2, but not limited thereto.

As shown in FIG. 1, the electronic device ED1 may further include a reflective component RC disposed between the top part 320t of the turning structure 320 of the back frame 300 and the light guide plate 200, wherein the reflective component RC is configured to reflect the light directed toward the turning structure 320 back to the light guide plate 200, so as to enhance the light-emitting quality of the electronic device ED1. At least a portion of reflective component RC may overlap the top part 320t of the turning structure 320 in the direction Z. The reflective component RC may include material(s) with high light reflectivity, such as metal material(s) with high light reflectivity. For example, the reflective component RC may include may include silver, aluminum, molybdenum, any other suitable metal material, and other suitable material with high light reflectivity or a combination thereof, but not limited thereto. The reflective component RC may be disposed on the top part 320t of the back frame 300 by any suitable method.

In the present disclosure, the reflective component RC may be designed based on requirement(s). As shown in FIG. 1, in the top-view direction (i.e., the direction Z) of the electronic device ED1, the reflective component RC may overlap the light emitting unit 120 and the light guide plate 200, so as to reflect the light directed toward the top part 320t of the turning structure 320 back to the light guide plate 200. As shown in FIG. 1, in the top-view direction of the electronic device ED1, a portion RC_1 of the reflective component RC may not overlap the top part 320t of the turning structure 320 of the back frame 300 (i.e., the reflective component RC may protrude from the top part 320t of the turning structure 320 in the cross-sectional view), and this portion RC_1 may overlap the light guide plate 200 and be substantially parallel to the light guide plate 200, so as to enhance the ability of the reflective component RC to reflect the light directed toward the top part 320t of the turning structure 320, and to reduce the light leakage of the electronic device ED1, but not limited thereto. Whether the reflective component RC and the reflective plate RL overlap in the direction Z may be designed based on requirement(s), but not limited thereto.

On the other hand, the reflective component RC and the light guide plate 200 are not in contact with each other, so as to reduce the difficulty of disposing the preassembling structure PS in the turning structure 320 of the back frame 300. A gap Gp exists between the reflective component RC and the light guide plate 200 in a normal direction of the light emitting circuit 100 (i.e., the direction Z), and this gap Gp may be greater than 0 and less than or equal to 1 mm, greater than 0 and less than or equal to 0.075 mm, greater than or equal to 0.075 mm and less than or equal to 1 mm, or greater than or equal to 0.04 mm and less than or equal to 0.07 mm, but not limited thereto.

The preassembling structure PS, the back frame 300, the reflective plate RL and the reflective component RC in the electronic device ED1 may be combined into a backlight module (i.e., a kind of lighting device), but not limited thereto.

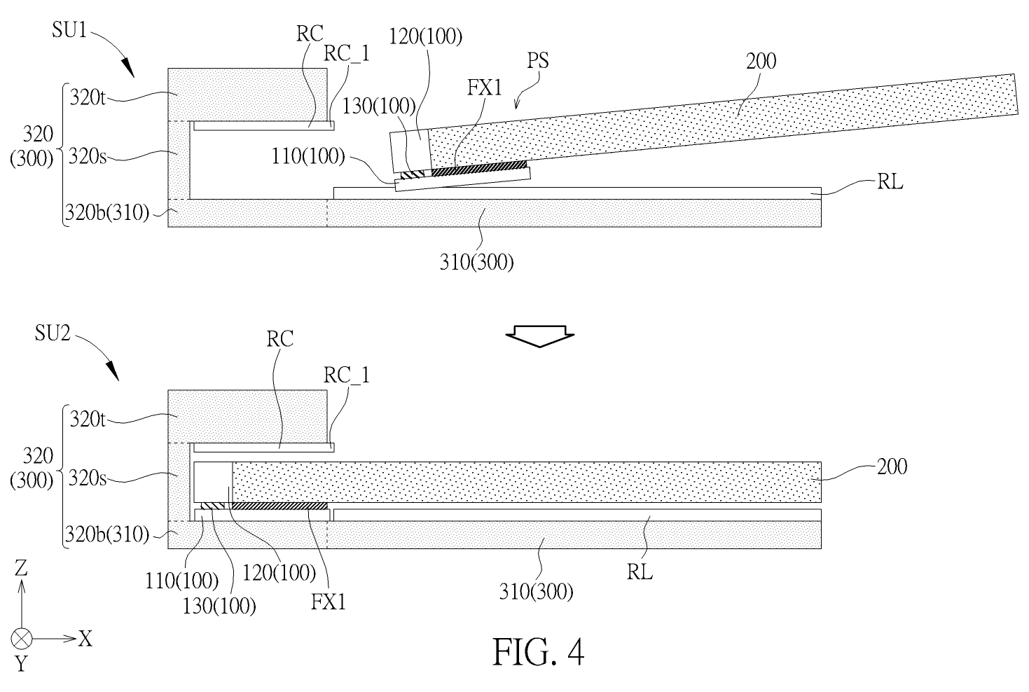

Referring to FIG. 4, FIG. 4 is a schematic diagram showing a part of an assembly process of an electronic device according to an embodiment of the present disclosure, wherein FIG. 4 omits the opposite-side structure 330 of the back frame 300. As shown in FIG. 4, before disposing the preassembling structure PS including the light guide plate 200, the light emitting circuit 100 and the fixing component FX1 in the turning structure 320 of the back frame 300, the reflective plate RL may be disposed on the bottom structure 310 of the back frame 300, and the reflective component RC may be disposed on the top part 320t of the back frame 300. Then, in the assembly process shown in FIG. 4, the preassembling structure PS is obliquely inserted into the turning structure 320 of the back frame 300, so as to make at least a portion of the light emitting circuit 100 and at least a portion of the light guide plate 200 be disposed in the turning structure 320. In FIG. 4, a status SU1 shows a moment that the preassembling structure PS is being obliquely inserted into the turning structure 320, and a status SU2 shows that the preassembling structure PS has been inserted into the turning structure 320.

During the process of obliquely inserting the preassembling structure PS into the turning structure 320 (e.g., the status SU1 shown in FIG. 4), one end of the board 110 of the light emitting circuit 100 may be in contact with the structure disposed on the bottom structure 310 of the back frame 300 (this end may be adjacent to the side part 320sof the turning structure 320 after inserting the preassembling structure PS into the turning structure 320). A shown in the status SU1 of FIG. 4, one end of the board 110 of the light emitting circuit 100 may be in contact with the reflective plate RL during the process of obliquely inserting the preassembling structure PS into the turning structure 320. Therefore, the present disclosure provides a design of this end of the board 110, so as to reduce the possibility of making defects (damages, dents, additional material residues, etc.) on the structure (e.g., the reflective plate RL) disposed on the bottom structure 310 of the back frame 300 when being in contact with this structure during the inserting process of the preassembling structure PS, thereby enhancing the yield rate and/or quality of the electronic device ED1.

As shown in FIG. 2 and FIG. 3, regarding the aforementioned end of the board 110, the base film 112 has an end part 112ep at this end. After inserting the preassembling structure PS into the turning structure 320, the end part 112ep is adjacent to the side part 320s of the turning structure 320, and the end part 112ep includes a first edge 110e1 of the board 110 (the base film 112) adjacent the side part 320s of the turning structure 320. In the present disclosure, the end part 112ep protrudes from the first protecting layer 118a, the first adhesive layer 116a, the second adhesive layer 116b and the second protecting layer 118b. Namely, the first protecting layer 118a, the first adhesive layer 116a, the second adhesive layer 116b and the second protecting layer 118b are not disposed on the end part 112ep of the base film 112, such that the end part 112ep of the base film 112 is not covered by the first protecting layer 118a, the first adhesive layer 116a, the second adhesive layer 116b and the second protecting layer 118b (i.e., the end part 112epof the base film 112 is not covered by any adhesive material). In some embodiments, the first protecting layer 118a, the first adhesive layer 116a, the second adhesive layer 116b and the second protecting layer 118b may be removed from the end part 112ep of the base film 112 by any suitable method. For example, the first protecting layer 118a, the first adhesive layer 116a, the second adhesive layer 116b and the second protecting layer 118b may be removed from the end part 112ep of the base film 112 by at least one etching process, but not limited thereto. In some embodiments, the first conductive layer 114a and the second conductive layer 114b may not be disposed on the end part 112ep of the base film 112, such that the end part 112ep of the base film 112 may be exposed, but not limited thereto.

In other words, the light emitting circuit 100 includes the first protecting layer 118a, the first adhesive layer 116a, the first conductive layer 114a, the base film 112, the second conductive layer 114b, the second adhesive layer 116b and the second protecting layer 118b stacked sequentially from top to bottom, wherein the base film 112 has the end part 112ep protruding from the first protecting layer 118a, the first adhesive layer 116a, the second adhesive layer 116b and the second protecting layer 118b, and the end part 112ep is adjacent to the side part 320s of the turning structure 320. Note that the content “the first protecting layer 118a, the first adhesive layer 116a, the first conductive layer 114a, the base film 112, the second conductive layer 114b, the second adhesive layer 116b and the second protecting layer 118b stacked sequentially from top to bottom” describes the positional relationship of these layers (as shown in FIG. 2), but the first protecting layer 118a, the first adhesive layer 116a, the first conductive layer 114a, the base film 112, the second conductive layer 114b, the second adhesive layer 116b and the second protecting layer 118b are formed or not formed in this sequence during the manufacturing process, and these layers would be formed by suitable ways.

In the present disclosure, a size (width) of the end part 112ep may be designed based on requirement(s). As shown in FIG. 3, in the top view, the width W (i.e., the size in the direction X) of the end part 112ep may be greater than 0 and less than or equal to 0.5 mm, greater than 0 and less than or equal to 0.45 mm, greater than 0 and less than or equal to 0.4 mm, or greater than 0 and less than or equal to 0.35 mm, but not limited thereto. In the present disclosure, the end part 112ep may be adjacent to the light emitting unit 120, and the end part 112ep may not overlap the light emitting unit 120 in the direction Z.

According to the above design, during the process of obliquely inserting the preassembling structure PS into the turning structure 320 (e.g., the status SU1 shown in FIG. 4), the end part 112ep of the base film 112 of the board 110 of the light emitting circuit 100 may be in contact with the reflective plate RL. Since the adhesive material (e.g., the first adhesive layer 116aand the second adhesive layer 116b) do not exist on the end part 112ep of the base film 112, even if the end part 112ep of the base film 112 of the board 110 of the light emitting circuit 100 is in contact with the reflective plate RL during the inserting process (assembly process), the possibility that the adhesive material (e.g., the first adhesive layer 116a and the second adhesive layer 116b) of the light emitting circuit 100 remains on the reflective plate RL is significantly reduced, so as to reduce the possibility of making defects on the reflective plate RL by the preassembling structure PS during the inserting process, thereby enhancing the yield rate and/or quality of the electronic device ED1.

Furthermore, in FIG. 3, the board 110 of the light emitting circuit 100 may optionally have a connecting part 110C configured to be connected to an outer device for receiving outer signal(s), wherein the end part 112ep and the connecting part 110C may be disposed on the same side of the base film 112. In FIG. 3, an extending direction of the connecting part 110C may be substantially perpendicular to the direction Y, wherein the direction Y may be an arranged direction of the light emitting units 120, but not limited thereto.

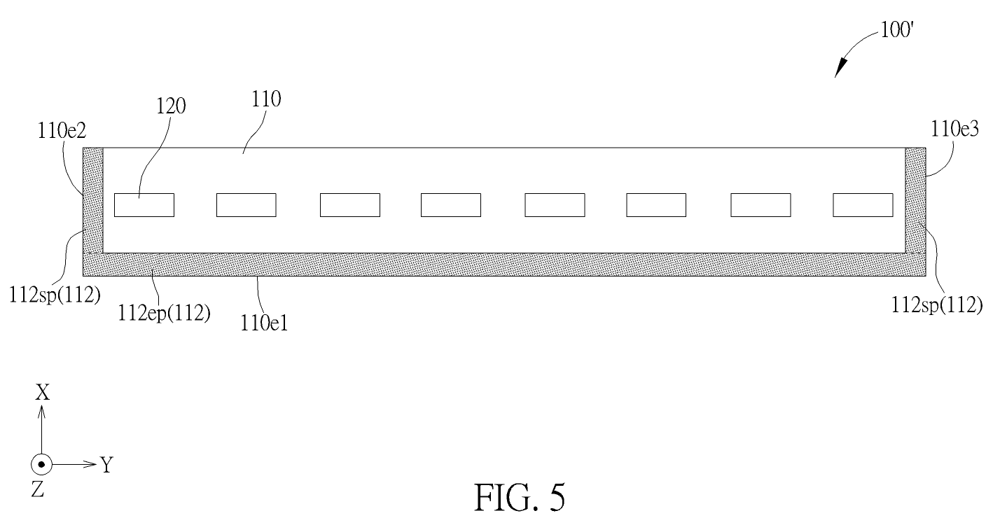

Moreover, in the light emitting circuit 100’ of another embodiment shown in FIG. 5, the adhesive material (e.g., the first adhesive layer 116aand the second adhesive layer 116b) is not disposed on not only the end part 112ep of the base film 112 but also two side end parts 112sp of the base film 112. The end part 112ep may be connected between two side end parts 112sp, and two side end parts 112sp respectively include a second edge 110e2 and a third edge 110e3 connected to the first edge 110e1, wherein an extending direction of the first edge 110e1 is different from an extending direction of the second edge 110e2 and/or an extending direction of the third edge 110e3. According to this design, the possibility that the adhesive material (e.g., the first adhesive layer 116aand the second adhesive layer 116b) remains on the reflective plate RL is more significantly reduced, so as to reduce the possibility of making defects on the reflective plate RL by the preassembling structure PS during the inserting process (assembly process), thereby enhancing the yield rate and/or quality of the electronic device ED1.

In some embodiments (as shown in FIG. 1), the electronic device ED1 may further include one optical film OL or a plurality of optical films OL, wherein the optical film OL is configured to suitably adjust the light. In FIG. 1, the optical film OL may be disposed on the bottom structure 310 of the back frame 300 and the preassembling structure PS in the top-view direction of the electronic device (i.e., in the direction Z), and be disposed between the turning structure 320 and the opposite-side structure 330 of the back frame 300 in the direction X. As shown in FIG. 1, the optical film OL may overlap the light guide plate 200 and not overlap the top part 320t of the turning structure 320 in the top-view direction of the electronic device (i.e., in the direction Z), but not limited thereto. In the present disclosure, the type of the optical film OL may be designed based on requirement(s). Each of the optical films OL1, OL2, OL3 and OL4 may include a diffuser, a prism, a lens or other suitable optical film.

As shown in FIG. 1, the electronic device ED1 may further include a display panel DP disposed on the back frame 300 and the preassembling structure PS, and the light emitted from the first surface 210a of the light guide plate 200 may emit toward the display panel DP.

In the present disclosure, the display panel DP may be designed based on requirement(s). In FIG. 1, the display panel DP may optionally include a light shielding layer LS, wherein the light shielding layer LS may be configured to separate sub-pixels in the display panel DP and to shield some components (e.g., the light shielding layer LS may shield components disposed on a peripheral region and/or shield regions overlapping the back frame 300), so as to enhancing the displaying quality. The light shielding layer LS may include metal, photoresist, ink, resin, pigment, other suitable light-shielding material or a combination thereof, but not limited thereto.

The electronic device of the present disclosure is not limited to the above embodiments. Further embodiments of the present disclosure are described below. For ease of comparison, same components will be labeled with the same symbol in the following. The following descriptions relate the differences between each of the embodiments, and repeated parts will not be redundantly described.

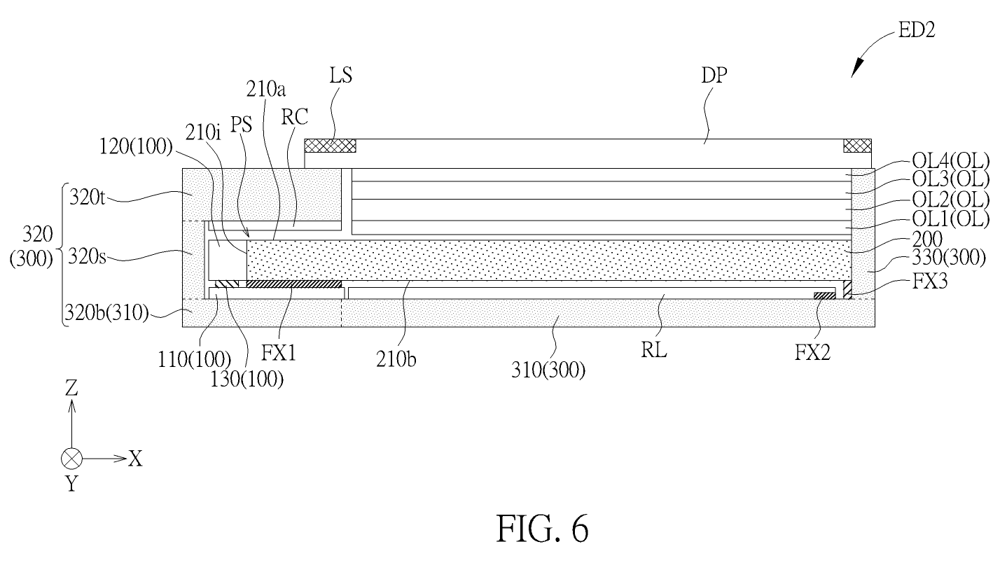

Referring to FIG. 6, FIG. 6 is a schematic diagram showing a cross-sectional view of an electronic device according to a second embodiment of the present disclosure. As shown in FIG. 6, a difference between this embodiment and the first embodiment is the design of the reflective component RC of the electronic device ED2 of this embodiment. In FIG. 6, the reflective component RC may completely overlap the top part 320t of the turning structure 320 in the direction Z, such that the reflective component RC may not protrude from the top part 320t of the turning structure 320.

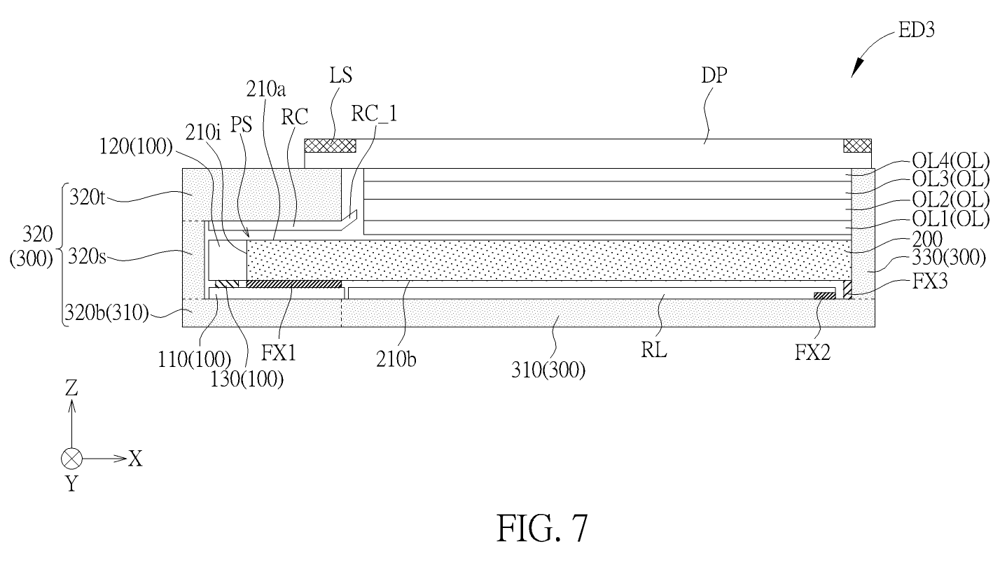

Referring to FIG. 7, FIG. 7 is a schematic diagram showing a cross-sectional view of an electronic device according to a third embodiment of the present disclosure. As shown in FIG. 7, a difference between this embodiment and the first embodiment is the design of the reflective component RC of the electronic device ED3 of this embodiment. In FIG. 7, the portion RC_1 of the reflective component RC may not overlap the top part 320t of the turning structure 320 of the back frame 300 (i.e., the reflective component RC may protrude from the top part 320t of the turning structure 320 in the cross-sectional view), and this portion RC_1 may overlap the light guide plate 200 and not be parallel to the light guide plate 200. As shown in FIG. 7, the protruding portion RC_1 of the reflective component RC may be oblique or bent toward the display panel DP, so as to reduce the difficulty of disposing (or assembling) the preassembling structure PS in the turning structure 320 of the back frame 300, but not limited thereto.

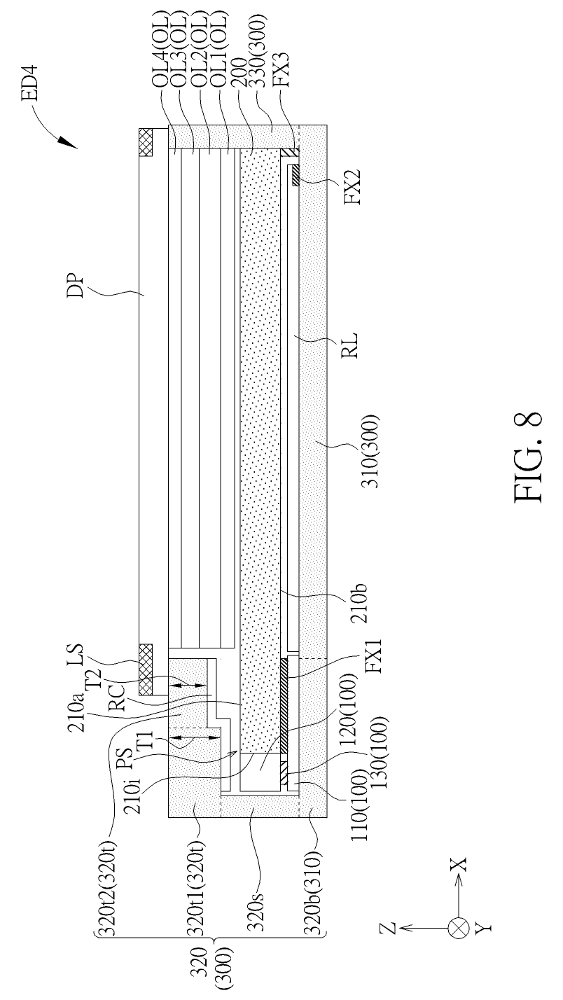

Referring to FIG. 8, FIG. 8 is a schematic diagram showing a cross-sectional view of an electronic device according to a fourth embodiment of the present disclosure. As shown in FIG. 8, a difference between this embodiment and the first embodiment is the designs of the back frame 300 and the reflective component RC of the electronic device ED4 of this embodiment. In FIG. 8, the top part 320t of the turning structure 320 of the back frame 300 may have a plurality of thicknesses, and the reflective component RC is arranged corresponding to the cross-sectional profile of the top part 320t of the turning structure 320. For instance, a thickness of a portion of the top part 320t closer to the side part 320s may be greater than a thickness of a portion of the top part 320t away from the side part 320s, so as to reduce the difficulty of disposing (or assembling) the preassembling structure PS in the turning structure 320 of the back frame 300. The top part 320t may include a first top portion 320t1 and a second top portion 320t2, the first top portion 320t1 may be between the side part 320s and the second top portion 320t2, and a thickness T1 of the first top portion 320t1 may be greater than a thickness T2 of the second top portion 320t2 in the direction Z, but not limited thereto.

In summary, since the base film of the board of the light emitting circuit of the present disclosure has the designed end part, even if the end part of the base film of the board of the light emitting circuit is directly in contact with the structure (e.g., the reflective plate) disposed on the bottom structure of the back frame during the inserting process (assembly process), the possibility that the adhesive material on the board remains on this structure (e.g., the reflective plate) is significantly reduced, so as to prevent from or reduce the possibility of making defects on this structure (e.g., the reflective plate) by the preassembling structure during the inserting process (assembly process), thereby enhancing the yield rate and/or quality of the electronic device.

Although the embodiments and their advantages of the present disclosure have been described as above, it should be understood that any person having ordinary skill in the art can make changes, substitutions, and modifications without departing from the spirit and scope of the present disclosure. In addition, the protecting scope of the present disclosure is not limited to the processes, machines, manufactures, material compositions, devices, methods and steps in the specific embodiments described in the description. Any person having ordinary skill in the art can understand the current or future developed processes, machines, manufactures, material compositions, devices, methods and steps from the content of the present disclosure, and then, they can be used according to the present disclosure as long as the same functions can be implemented or the same results can be achieved in the embodiments described herein. Thus, the protecting scope of the present disclosure includes the above processes, machines, manufactures, material compositions, devices, methods and steps. Moreover, each claim constitutes an individual embodiment, and the protecting scope of the present disclosure also includes the combination of each claim and each embodiment. The protecting scope of the present disclosure shall be determined by the appended claims.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. An electronic device, comprising:
a back frame having a turning structure, wherein the turning structure comprises a bottom part, a top part and a side part connected between the bottom part and the top part;
a light emitting circuit; and
a light guide plate, wherein the light guide plate and the light emitting circuit are fixed through a first fixing component;
wherein the light emitting circuit and the light guide plate fixed to each other are disposed in the turning structure;
wherein the light emitting circuit comprises a first protecting layer, a first adhesive layer, a first conductive layer, a base film, a second conductive layer, a second adhesive layer and a second protecting layer which are stacked sequentially from top to bottom;
wherein the base film has an end part protruding from the first protecting layer, the first adhesive layer, the second adhesive layer and the second protecting layer, and the end part is adjacent to the side part of the turning structure.

2. The electronic device of claim 1, wherein the end part protrudes with a width, and the width is greater than 0 and less than or equal to 0.5 mm.

3. The electronic device of claim 1, wherein the light emitting circuit further comprises a light emitting unit, and the light emitting unit is in contact with the light guide plate.

4. The electronic device of claim 1, further comprising a reflective component disposed between the top part of the turning structure and the light guide plate, wherein the reflective component is not in contact with the light guide plate.

5. The electronic device of claim 1, further comprising a reflective plate disposed under the light guide plate, wherein the reflective plate and a side of the back frame away from the turning structure are fixed through a second fixing component.

6. The electronic device of claim 1, wherein the light guide plate and a side of the back frame away from the turning structure are fixed through a third fixing component.

7. The electronic device of claim 1, wherein the light emitting circuit further comprises a light emitting unit, the first protecting layer has a first hole, the first adhesive layer has a second hole, and the light emitting unit is electrically connected to the first conductive layer through the first hole and the second hole.

8. The electronic device of claim 1, further comprising an optical film, wherein the optical film overlaps the light guide plate and does not overlap the top part of the turning structure in a top-view direction of the electronic device.
